(19) United States
(12) Patent Application Publication
(10) Pub. No.: US 2024/0145601 A1
(43) Pub. Date: May 2, 2024

(54) STRESS-CONFIGURABLE NANOELECTRONIC COMPONENT STRUCTURE, INTERMEDIATE PRODUCT, AND METHOD FOR PRODUCING A NANOELECTRONIC COMPONENT STRUCTURE

(71) Applicant: TECHNISCHE UNIVERSITÄT CHEMNITZ, Chemnitz (DE)

(72) Inventors: Sascha Hermann, Chemnitz (DE); Simon Böttger, Gornau (DE); Eric Pankenin, Chemnitz (DE)

(21) Appl. No.: 18/562,429

(22) PCT Filed: Apr. 14, 2022
(86) PCT No.: PCT/IB2022/053524

§ 371 Date: Nov. 20, 2023

(30) Foreign Application Priority Data
May 18, 2021 (DE) 10 2021 112 863.3

(51) Int. Cl. H01L 29/84; B82Y 40/00

(52) U.S. Cl. CPC H01L 29/84; B82Y 40/00

(57) ABSTRACT

An intermediate product for producing a nanoelectronic component structure and a nanoelectronic component structure, each have a substrate, a cavity formed therein, and a nanostructure which partly spans the cavity. A method for producing a nanoelectronic component structure, includes the steps of introducing a cavity into the substrate, and each cavity is bridged by at least one nanostructure. This allows mechanical stress states in nanostructures to be adjusted in a decoupled manner from location and direction. This is achieved in that the nanoelectronic component structure has an arm, which partly overlaps with the cavity, on one side of the respective cavity, the arm being bent or shrunk at the arm end protruding beyond or into the respective cavity. A gap is formed over the cavity, and the nanostructure is arranged on the respective arm so as to span the respective gap and is fixed between the respective arm and contact electrodes formed on each side of the gap.

The present invention relates to an intermediate product for producing a nanoelectronic component structure, the intermediate product having a substrate, at least one cavity formed in the substrate and at least one nanostructure at least partially spanning the corresponding cavity. The invention further relates to a nanoelectronic component structure which has a substrate, at least one cavity formed in the substrate and at least one nanostructure at least partially spanning the corresponding cavity. In addition, the invention relates to a method for producing a nanoelectronic component structure in which at least one cavity is made in a substrate and the corresponding cavity is bridged by at least one nanostructure.

Modern electronics require ever more functionality in terms of material together with reduced space and energy requirements in order to meet the requirements of today's society and industry.

In this case, 1D and 2D nanomaterials or nanostructures based thereon are predestined to be used here on account of their usually extraordinary intrinsic properties such as dimensionality, load-bearing capacity, electronic properties, highest degree of sensitivity and quality together with reduced energy dissipation.

Graphene, a modification of carbon having a two-dimensional structure in which each carbon atom is surrounded by three others at an angle of 120° such that a honeycomb pattern is formed is currently the most sought-after and most studied nanomaterial. From the class of 1D nanomaterials, nanotubes are used, for example, i.e. elongate hollow bodies having a diameter of less than 100 nm. In this case, carbon nanotubes, for example, are known and well studied. Likewise, nanowires made of silicon and various other materials exist.

In the meantime, for example one-dimensional nanostructures such as carbon nanotubes, are found in a wide variety of industry-relevant applications, such as in sensors, radio-frequency transceivers, non-volatile memories, digital architectures and security primitives for hardware. However, for many of these applications, there is still a lack of suitable scalable and reproducible integration technologies in order to make the aforementioned excellent properties usable in an extensive manner within domains of constant physical structure and alignment of the nanomaterials, the corresponding extension of a domain lying in the one-digit to two-digit micrometer range. The extraordinarily high sensitivity factors for selected domain structures of piezoresistive sensors made of nanomaterials are representative of the incisive influence of mechanical voltage states. These are usually only measured in individual components, but because of insufficient comparability of the domains with one another, these have not yet been manufactured in high quantities.

Here, for example, undefined tension and structural assembly states of the nanomaterials can cause the emergence of parasitic surface distortions or effects such as slip-stick behavior in one-dimensional and two-dimensional piezoresistive sensors or nanoresonators can occur, which lead to degradation of the performance behavior, such as hysteresis, drift and increased variance of the component properties, such as band gaps, charge carrier mobility and/or resonant frequencies. The surface distortions prevent, for example, a homogeneous and crease-free transfer of graphene onto a target substrate, and also impair the electrical properties by the electronic material structure being changed locally.

In addition to said parasitic effects, due to the small area moment of inertia of nanomaterials, it has hitherto not been possible to detect mechanical compressive stress by means of piezoresistive sensors made of nanomaterial. The intrinsic variability of nanomaterials is a further difficulty, due to different assembly symmetry of two-dimensional nanostructures and the chirality of one-dimensional nanostructures, which inherently causes variability of the electronic properties. In the past, this prevented the production of typical compensation circuits, such as half or full bridges.

Nanomaterials indisputably have an enormous potential to decisively influence the “Beyond-CMOS” era, on the basis of novel electronic concepts, such as 3D hyperintegration. However, there are currently no controllable, scalable and reproducible integration technologies in which, for example, it is possible to control the mechanical tension state of nanostructures.

There are approaches in the prior art for targetedly setting or influencing the mechanical tension state of nanomaterials.

Thus, permanent tensioning of nanomaterial components produced can be set by certain surface technologies.

For example, it is conceivable, in principle, to apply cover layers, acting as stressors, to nanomaterials, as is known from conventional silicon-based MOSFET technology, and to structure them if necessary. However, this is associated with enormous challenges in terms of process compatibility and therefore nothing has been disclosed in this regard.

Furthermore, technologies are known in which the relevant nanomaterial zone is freed and subsequently modified in order to produce fixed tensioning.

In addition, it is possible to introduce pretension into the nanomaterial directly during the nanomaterial integration. For this purpose, a transfer carrier membrane can be used, which is mechanically stretched during the transfer of the nanomaterial onto the structure to be formed. By means of such a technology, however, tension cannot be introduced into the nanomaterial either in a locally variable manner or multidirectionally.

Furthermore, a temporary local modification of the tension state of spanned nanomaterials can be carried out by using, for example, a probe or a movable MEMS actuator system made directly on the sample in question. However, due to the high complexity and the high demands in manufacturing technologies and operating conditions, such components are suitable only for single-component tests, but not for scalable implementation in industry-relevant applications.

In order, for example, to locally modify the tension state of nanomaterials using probe-microscopic methods, an immensely high use of downstream control electronics and peripheral systems, e.g. for vibration damping, is necessary. In addition, effects which are caused by the tension or the deformation of the nanomaterial on the probe, and stray fields of the probe, are no longer clearly distinguishable from one another.

Thermal or electrostatic MEMS actuators combined with integrated nanomaterials are associated with an extreme space requirement and resource-intensive MEMS technology compared to the corresponding nanocomponent, and thus cannot be used in a scalable manner for series production. In addition, the tension in the nanomaterials in these components is highly susceptible to vibrations and inertial movements without further efforts, and, under certain circumstances, additional energy is required for operating the actuator. The operating principle of the actuators additionally introduces parasitic effects, such as potential and/or temperature gradients, into the system.

Furthermore, in order to induce mechanical tension, a weight placed on or at a membrane, made of nanomaterial, that spans a cavity can be used, or a pressure difference can be formed between a membrane made of nanomaterial and a gas, fluid or solid volume surrounded by this membrane in a cavity. Apart from the technological and actuator-related additional effort and comparatively large space requirements, and thus limited scalability, in such arrangements the tensioning directions are mostly distributed in all spatial directions such that a locally very precise placement of the nanomaterial would be necessary to ensure the tension states applied.

In summary, hitherto no nanomaterial components have been demonstrated which have been produced at a wafer level in scalable, parallel manufacturing, and simultaneously make it possible to make the intrinsic tension state-dependent effects within a nanomaterial domain limit or from different nanostructures having high surface density accessible so as to targetedly control and scale them. Rather, technologically highly complex and resource-intensive approaches such as MEMS technologies or probe manipulation have been demonstrated on mostly individual parts. However, these approaches require a comparatively large amount of space for the manipulation tools of the nano-objects.

The object of the present invention is therefore to provide a nanoelectronic component structure that can be produced using existing integration technologies, having mechanical tension that is adjustable in a defined manner, and optionally an intermediate product for the production of said nanoelectronic component structure. Furthermore, a method for producing a nanoelectronic component structure, which can be adjusted with regard to its mechanical tension, is to be proposed, which method is compatible with existing integration technologies.

This object is achieved, on the one hand, according to the invention by an intermediate product for producing a nanoelectronic component structure, the intermediate product having a substrate, at least one cavity formed in the substrate and at least one nanostructure which at least partially spans the corresponding cavity, the cavity being at least partially filled with a sacrificial material which can be etched out or dissolved out selectively, relative to the material of the substrate, and the intermediate product having either at least one arm which partially overlaps the at least one cavity at least on one side of the corresponding cavity and has a gap which is formed above the at least one cavity, or at least one arm which spans the cavity and has a predetermined breaking point which is formed above the at least one cavity, the at least one nanostructure being arranged on the at least one arm, in each case spanning the gap or the predetermined breaking point, and in each case being covered by a contact electrode on both sides of the gap or the predetermined breaking point.

Proceeding from the intermediate product according to the invention, the formation of a nanoelectronic component structure having locally controllable or locally adjustable mechanical tension states is possible.

For this purpose, the intermediate product comprises the substrate, in which the at least one cavity, in each case filled with the sacrificial material, is formed. The substrate can be formed, for example, from silicon or another semiconductor material. Other microelectronic and/or micromechanical structures, such as electrical connections, electrodes, channels, membranes, etc. can also be provided in, on or below the substrate.

In the intermediate product according to the invention, the sacrificial material forms a suitable substrate for depositing the at least one arm and for applying the at least one nanostructure. In addition, the corresponding arm located on the sacrificial material can be effectively structured thereon or deposited thereon in an effectively structured manner so as to result in the gap or the predetermined breaking point above the corresponding cavity.

The sacrificial material is selectively etchable or dissolvable unlike the material of the substrate such that it can be removed therefrom without impairing the substrate material. After such an at least partial removal of the sacrificial material, the part of the arm which projects over the cavity no longer has any physical contact with the sacrificial material and can therefore relax, whereby targeted bending of the arm ends of the arm and of the nanostructure located thereon can be produced, whereby a particular mechanical tension can thus be introduced into the nanostructure in a targeted manner. Furthermore, arm ends exposed by the removal of the sacrificial material can be treated in such a way that a certain tension builds up therein, by means of which the nanostructure located on the corresponding arm end can be tensioned.

If a gap above the cavity is already present between two arms each extending partially over the cavity, an arm end of the arm located next to the gap can, depending on the existing preload of the corresponding arm, bulge into the exposed interior of the cavity after such an at least partial removal of the sacrificial material, or can bulge away from the cavity, or remain straight.

If an arm extending over the cavity initially only has a predetermined breaking point above the cavity, the predetermined breaking point can be perforated, for example by means of ultrasound or by mechanical action, whereby free arm ends are produced on both sides of the perforated predetermined breaking point, at least one of which, depending on the existing preload of the corresponding arm, can, after the at least partial removal of the sacrificial material, bulge into the exposed interior of the cavity or can bulge away from the cavity, or can remain straight above the cavity. The predetermined breaking point is a pre-structured separating or tear-open point. It forms a retaining element that can be removed or opened retrospectively, the removal or opening of which makes it possible to release a tension state originally introduced into the corresponding arm and thereby tension the nanostructure.

The predetermined breaking point can be severed by external mechanical and/or thermal and/or subtractive stimulation.

Since the corresponding nanostructure is located on the at least one arm, it bends together with the corresponding arm end, i.e. either into the cavity or away from the cavity, or remains straight above the cavity.

In this case, the at least one nanostructure is held in each case on both sides of the cavity by one of the contact electrodes.

In a preferred embodiment of the intermediate structure according to the invention, the at least one arm is under mechanical tensile stress. In this embodiment of the invention, after the at least partial removal of the sacrificial material, at least one of the arm ends exposed thereby, and thus also the nanostructure located thereon, bends into the cavity.

Due to the mechanical preloading or pre-setting of the at least one arm, both its electronic material properties, such as charge carrier mobility, and its component properties, such as quality and resonant frequency, can be improved and even controlled in a nanoelectronic component structure produced from the intermediate product.

Although in the present invention there are no exceptions with regard to what nanomaterials can be used for the at least one nanostructure, graphene and/or at least one carbon nanotube are particularly well suited to the formation of the at least one nanostructure. These nanomaterials can be easily integrated into existing manufacturing technologies.

It has proven to be advantageous to use copper, tungsten, silicon dioxide and/or aluminum oxide as the sacrificial material, since these materials can be easily deposited and have the required etching selectivity to silicon as the substrate material. In principle, however, other sacrificial materials can also be used. The corresponding sacrificial material should be selectively removable from the corresponding cavity, with respect to the substrate material used. Thus, the sacrificial material can be both inorganic and organic. In addition, the sacrificial material can be removable either dry or wet using subtractive methods.

In an advantageous embodiment of the intermediate product according to the invention, at least one control electrode is arranged or formed in at least one of the at least one cavity. The corresponding control electrode consists of at least one electrically conductive material. In the intermediate product, the corresponding control electrode typically is located on the base of the cavity, below the sacrificial material, and can thus be exposed by removing the sacrificial material. By means of the control electrode, charge carrier influencing can be performed in the nanostructure, similarly to a gate electrode in MOSFET structures. In the present invention, on account of the structure and method, an adjustable distance can be set between the control electrode and the corresponding nanostructure in a self-limiting manner via the thickness of the sacrificial material and/or the corresponding arm. In addition, in this embodiment of the invention, the depth of the cavity and the thickness as well as the length of the corresponding arm projecting beyond the cavity at the cavity edge in each case, can be selected such that the arm end rests on the control electrode after removal of the sacrificial material, i.e. thus resulting in “gate-touchdown” of the arm on the control electrode.

The object is also achieved according to the invention by a nanoelectronic component structure which has a substrate, at least one cavity formed in the substrate and at least one nanostructure which at least partially spans the corresponding cavity, the nanoelectronic component structure having at least one arm which partially overlaps the at least one cavity at least on one side of the corresponding cavity and is curved or shrunk on its arm end projecting beyond or into the corresponding cavity, a gap being formed over the at least one cavity and the at least one nanostructure being arranged on the at least one arm, in each case in a manner spanning the gap, and being fixed between the at least one arm and contact electrodes each formed on either side of the gap.

The nanoelectronic component structure according to the invention can be formed from one embodiment of the intermediate product described above.

In contrast to the intermediate product described above, in the nanoelectronic component structure according to the invention there is no sacrificial material, or only so little sacrificial material, in the cavity that the at least one arm is exposed above the cavity.

In the nanoelectronic component structure according to the invention, the at least one arm is relaxed by the at least partial removal of the supporting sacrificial material from the corresponding cavity and is thereby bent vertically, and/or contracts horizontally by shrinking. Due to the relaxation of the intrinsic tension states and/or the targeted introduction of tension due to the shrinkage, in the nanoelectronic component structure according to the invention, the lateral projection of the corresponding arm is shortened in comparison with its lateral extension in the intermediate product. Since, in addition, in the nanoelectronic component structure according to the invention the at least one nanostructure is arranged on the at least one arm so as to span the gap in each case and is fixed between the at least one arm and the contact electrodes formed in each case on either side of the gap, the nanostructure is tensioned. The nanostructure is thus offset in the stretched position in the nanoelectronic component structure according to the invention.

In the nanoelectronic component structure according to the invention, the at least one nanostructure has a mechanical tension that is set by the curvature and/or shrinkage of at least one arm end.

If at least one arm end bulges into the cavity, the at least one nanostructure, which is arranged on the at least one arm and thus also bulges into the cavity, is tensioned. The at least one nanostructure is then mechanically tensioned between the contact electrodes.

The same applies if at least one arm end bulges in such a way that it bulges away from the cavity, and as a result the nanostructure located on the at least one arm also bulges away from the cavity.

If at least one arm end is shrunk, the at least one nanostructure that lies on the corresponding arm end, is fixed in position there in each case by means of an electrode and extends over the cavity, is stretched, i.e. tensioned.

That is to say that, in the case of any bending or deformation of the at least one arm caused by relaxation or shrinkage, the lateral projection of said arm also changes such that fixed points between the arm and the nanostructure located thereon move away from one another, whereby a tensile stress is introduced into the nanostructure.

Since, in the nanoelectronic component structure according to the invention, the at least one nanostructure extends over the corresponding cavity, the corresponding nanostructure is decoupled from the substrate in the functionally active region, as a result of which the properties of the nanostructure can be kept free of parasitic influences of the substrate. The nanoelectronic component structure according to the invention thus has at least one preloaded nanostructure that is decoupled from the substrate.

The decoupling from the substrate is important for suppressing parasitic interactions with the substrate, for example when the nanoelectronic component structure according to the invention is used as a nanoresonator or has at least one nanoresonator.

The nanoelectronic component structure according to the invention can, for example, also be a piezoresistive nanomaterial strain sensor which is capable of first detecting compressive stress by the preloading of the at least one nanostructure.

The nanoelectronic component structure according to the invention has the advantage that it can be produced in a scalable and reproducible manner by means of conventional surface technologies.

Furthermore, the nanoelectronic component structure according to the invention is extremely energy-efficient, since no peripheral equipment is required, which actively preloads the at least one nanostructure and consumes energy. The preload that is or can be set in the at least one nanostructure is permanent.

In preferred embodiments of the nanoelectronic component structure according to the invention, the at least one nanostructure is tensioned between the contact electrodes.

In one embodiment of the nanoelectronic component structure according to the invention, a side of the at least one nanostructure facing away from the substrate is preferably more strongly tensioned than a side of the at least one nanostructure facing the substrate. In order to achieve this, a side of the arm pointing away from the substrate and on which the corresponding nanostructure is arranged can be shrunk more strongly than a side of this arm adjacent to the substrate, for example.

In order, for example, to be able to control a current flow in the at least one nanostructure, it is advantageous if at least one control electrode is arranged in at least one of the at least one cavities. Such a control electrode is preferably arranged at the base of the corresponding cavity.

In an advantageous development of the invention, the substrate has a plurality of the cavities which are each spanned by at least one of the nanostructures, at least two of the cavities having different widths and/or depths and/or lengths and/or at least two of the nanostructures having different widths and/or lengths and/or at least two of the nanostructures being aligned in different spatial directions and/or being mechanically tensioned. The respective nanostructures can thus be designed having different tension levels and/or tension orientation, as a result of which they can be designed for different measurement ranges and/or for detecting different force or tension vectors. Furthermore, in this way possible measurement errors can be compensated for and/or measurement signals can be amplified by the respective nanostructures, since, for example, in the case of piezoresistive half-bridge circuits, both sensor and compensation elements can be realized within a zone of homogeneous properties, i.e. within the domain boundary of the corresponding nanostructure.

In preferred embodiments of the nanoelectronic component structure according to the invention, the at least one nanostructure comprises graphene and/or at least one carbon nanotube. However, for the formation of the at least one nanostructure, other nanomaterials, such as nanowires having a diameter in a range of up to a maximum of 100 nm made of other metals, non-metals or semiconductors, are also suitable.

In a favorable embodiment of the invention, at least in the at least one cavity, a shrunk filler material is located, on which at least one arm end rests or into which at least one arm end is integrated. Thus, in the nanoelectronic component structure according to the invention, at least one of the arms can or will be brought into a new, permanently defined tension state due to the omission of the previous arm fixing process as a result of the sacrificial material removal and by means of the corresponding arm resting on or being integrated into the shrunk filler material.

The filler material can be a material which, in addition to the shrinkage property, also fulfills other purposes, such as the passivation of at least part of the nanoelectronic component structure and/or the fixing of at least one element of the nanoelectronic component structure. For example, hermetic shielding of the nanomaterial of the corresponding nanostructure can be achieved by the passivation.

Conversely, if the tensile loading of the corresponding nanostructure is carried out solely by the relaxation of tensioned arm ends, a passivation material can be used which does not have any shrinkage properties.

Alternatively, by means of shrinking passivation, a nanostructure can be tensioned which is located, for example, on arms formed from just a single layer and which are previously not tensioned at all.

Bending of the at least one arm and thus tensioning of the at least one nanostructure can be permanently maintained if at least one arm end of the corresponding arm projecting into the at least one cavity is fixed in position by a filler material introduced into the corresponding cavity.

It is also possible to cover the at least one nanostructure itself with the filler material in order to obtain its tension state.

The filler material is preferably a material which, in addition to the fixing property, also fulfills other purposes, such as passivation of at least part of the nanoelectronic component structure, and/or is shrinkable.

In the present invention, the same filler material can thus be used to set the tension of the corresponding nanostructure by means of shrinkage of the filler material and/or to fix at least one exposed arm and/or nanostructures and/or for passivation.

If at least one mass body is arranged on each of the at least one nanostructures, deflections of the at least one nanostructure can be amplified and/or the resonant frequency of the corresponding nanostructure can be set, and thus frequency-dependent amplification and/or filtering of signals can be achieved. The mass body can, for example, be formed from an exposed and/or freed part of the corresponding arm on which the nanostructure rests. For example, the part of the arm may have become a seismic mass, by dissolving the sacrificial material out of the cavity, which mass is held by the nanostructure.

For example, miniaturized sensor-type compensation circuits, such as bridge or half-bridge circuits, can be formed with or on the basis of at least one nanoelectronic component structure according to the invention. Such circuits can thus be realized within the domain size of the nanostructure used in each case.

This results in reproducible and homogeneous component properties over several components produced in parallel. The bridge or half-bridge circuit makes it possible to design self-calibrating components having the highest possible signal-to-noise ratio and/or integrated drift correction.

The object is also achieved according to the invention by a method for producing a nanoelectronic component structure, in which at least one cavity is made in a substrate and the corresponding cavity is bridged by at least one nanostructure, the at least one cavity being at least partially filled with a sacrificial material, at least one arm which partially overlaps the at least one cavity on at least one side of the corresponding cavity and has a gap formed above the at least one cavity, or at least one arm which spans the corresponding cavity and has a predetermined breaking point above the at least one cavity, being formed, the at least one nanostructure being formed or arranged on the at least one arm so as to span the corresponding gap or predetermined breaking point, in each case a contact electrode being formed on nanostructure ends of the corresponding nanostructure formed on either side of the corresponding cavity, subsequently the sacrificial material is at least partially etched out or dissolved out of the corresponding cavity, and, if present, the predetermined breaking point is broken through.

The method according to the invention can be used to produce nanoelectronic component structures having locally controllable or locally targetedly settable mechanical tension states. In particular, defined tension states can be introduced in a location-specific and adaptable manner into individual 1D or 2D nanostructures or groups thereof.

In this case, it is possible to set the tension of the at least one nanostructure in the sub-micrometer range, which also enables the creation of arrays having variable individual component properties in the smallest space. This is regarded, for example, as a basic prerequisite for imaging broadband sensors for mechanical stress, atomic/chemical species of the surroundings, and for optical radiation.

The method steps of the method according to the invention are compatible with existing monolithic integration technologies. The method according to the invention can thus be easily integrated into existing manufacturing processes or into a hetero-system integration. The method according to the invention is also compatible with Beyond-CMOS technologies and in system-on-chip technologies. Novel hybrid components with linked functionality consisting of sensors, actuators and electronics can thus be created.

No high temperatures are necessary for the method according to the invention. This results in process compatibility.

In the method according to the invention, particularly high reproducibility of the component production can be achieved by self-limiting deposits of the nanomaterial used to form the at least one nanostructure.

However, it is also possible to produce the at least one nanostructure independently of the manufacturing process of the substrate, and ultimately to transfer it thereto. Such a procedure has the advantage of eradication of incompatibilities in the production line, which entails the use of conventional processes. By means of this transfer approach, there is additionally the possibility of introducing further mechanical preloading into the nanomaterial of the corresponding nanostructure directly during the transfer of the at least one nanostructure to the substrate.

In this procedure, the at least one preferably previously ordered and aligned nanostructure is positioned on the previously processed substrate. The electrical contacting of the at least one nanostructure follows, by means of a lithography technology adapted therefor, and the at least one arm having the at least one nanostructure located thereon is freed, whereby a predefined tension is set in the at least one nanostructure.

The method according to the invention allows for the production of self-referencing or self-calibrating circuits comprising nanoelectronic component structures which are created within a domain of the particular nanomaterial, which also compensates for the inherent drift in the component properties.

In preferred embodiments of the method according to the invention, at least one of the arms is formed from at least two layers of materials, using process parameters and with layer thicknesses of such a type that it is under mechanical tensile stress directly after the layer deposition steps, i.e. has a residual layer tension. In these embodiments, the corresponding arm is designed, for example, as a tensioned double layer, which relaxes after the at least partial removal of the sacrificial material from the cavity.

However, tension can also be introduced into the corresponding arm only after the deposition thereof, for example by virtue of the fact that arm ends of the corresponding arm are shrunk by means of tempering after said arm has been freed by the removal of the sacrificial material.

The arrangement of at least one control electrode in the region around the at least one nanostructure offers enhanced functionality. One or more such control electrode(s) can, for example, in one embodiment of the method according to the invention, be arranged or formed in at least one of the at least one cavity before it is at least partially filled with the sacrificial material. The corresponding control electrode can preferably be formed on the base of the corresponding cavity. Since the process of dissolving out or etching out the sacrificial material from the at least one cavity, which process if used in the method according to the invention, is a self-adjusting process, it is thus possible to set the preload not only in a design-determined manner, but rather also in the process to influence suitable component properties, such as the distance from the control electrode to the at least one nanostructure, and thus the working point of the nanoelectronic component structure formed.

An array or module having different nanostructures and thus covering different measuring or functional regions can be designed with the aid of the method according to the invention, if, herein, at least two of the cavities are each formed having different widths and/or depths and/or lengths and/or at least two of the nanostructures are designed to be aligned in different spatial directions in each case and/or are mechanically tensioned in different spatial directions in each case. By means of this technology, nanostructures oriented in different spatial directions, i.e. multidirectional nanostructures, can be produced in parallel. The respective geometries and/or alignments of the nanostructures can be used to precisely scale these.

It is thereby possible to integrate nanostructures, selected with regard to their properties, with controllable arrangement into the array or the module.

By using self-arranging effects, a parallel alignment of the nanostructures over the substrate can also be achieved.

Nanoelectronic component structures having good reproducibility can be produced using the method according to the invention if graphene and/or at least one carbon nanotube is/are used as the material(s) for the formation of the at least one nanostructure.

The corresponding arm can also be tensioned in a defined manner in that, after the at least partial etching out or dissolving out of the sacrificial material from the at least one cavity, at least one filler material is introduced into the corresponding cavity and said material is subsequently shrunk by tempering and/or curing.

After relaxation of the arm by the at least partial removal of the sacrificial material from the corresponding cavity, in an advantageous embodiment of the method according to the invention, arm ends projecting into the at least one cavity can be fixed by introducing a filler material into the corresponding cavity.

In this case, the filler material can also be applied to the at least one nanostructure in order to fix it and thus maintain the tension introduced therein.

Although a very wide variety of filler materials can in principle be used in the present invention, it has proven to be advantageous for achieving good shrinkage properties if the at least one filler material comprises at least one silsesquioxane, for example hydrogen silsesquioxane, and/or at least one crosslinking polymer.

Particularly effective deflectability of the at least one nanostructure can be achieved if, in one embodiment of the method according to the invention, in each case at least one mass body is formed on the at least one nanostructure. In this case, the at least one mass body in the present invention can function, for example, as an inert mass for an inertial sensor and/or mechanical resonator or as an element of a plate capacitor for producing a MEMS/NEMS actuator system.

In a preferred embodiment of the method according to the invention, the at least one mass body is formed from the at least one arm while the sacrificial material is at least partially etched or dissolved out of the at least one cavity.

The tension in the at least one nanostructure can be controlled particularly effectively if the at least one nanostructure is applied to the at least one arm by means of a stretched transfer carrier. By means of the stretched transfer carrier, a preloaded nanomaterial layer can be applied, for example, to the entire substrate, from which, by corresponding geometric design of the at least one cavity located therebelow and of the at least one arm extending over the corresponding cavity, at least one nanostructure having a controlled tension and tension direction in the sub-micrometer range can then be formed.

Preferred embodiments of the present invention, its design, function and advantages are explained in more detail below with reference to figures, wherein

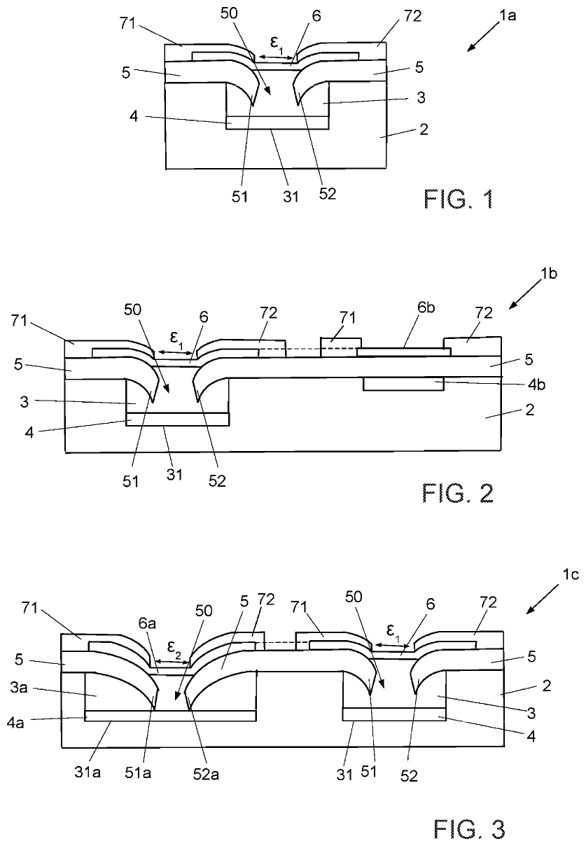

FIG. 1 is a schematic sectional side view of an embodiment of a nanoelectronic component structure according to the invention;

FIG. 2 is a schematic sectional side view of a further embodiment of a nanoelectronic component structure according to the invention;

FIG. 3 is a schematic sectional side view of yet another embodiment of a nanoelectronic component structure according to the invention;

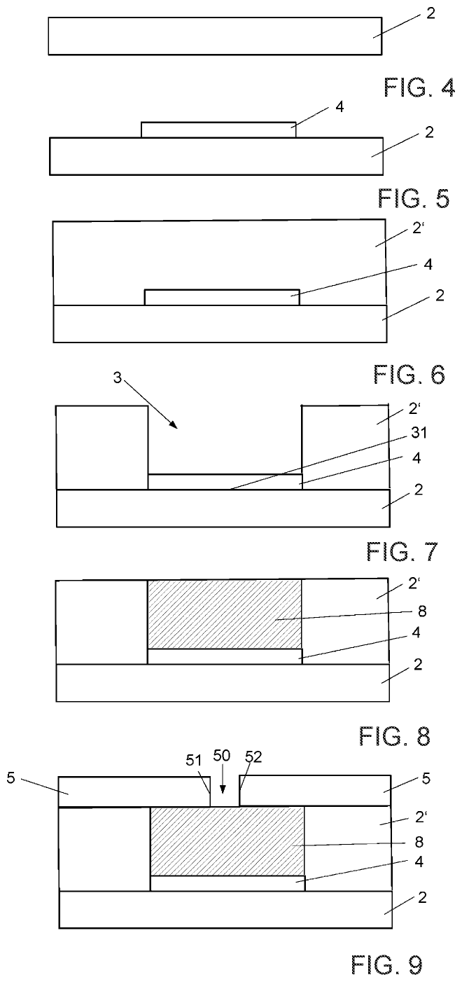

FIGS. 4 to 12 schematically show method steps of one embodiment of the method according to the invention for producing the nanoelectronic component structure from FIG. 1, in each case in a sectional side view through the structure formed in each case;

FIG. 13 shows the nanoelectronic component structure from FIG. 12 comprising introduced and applied filler material;

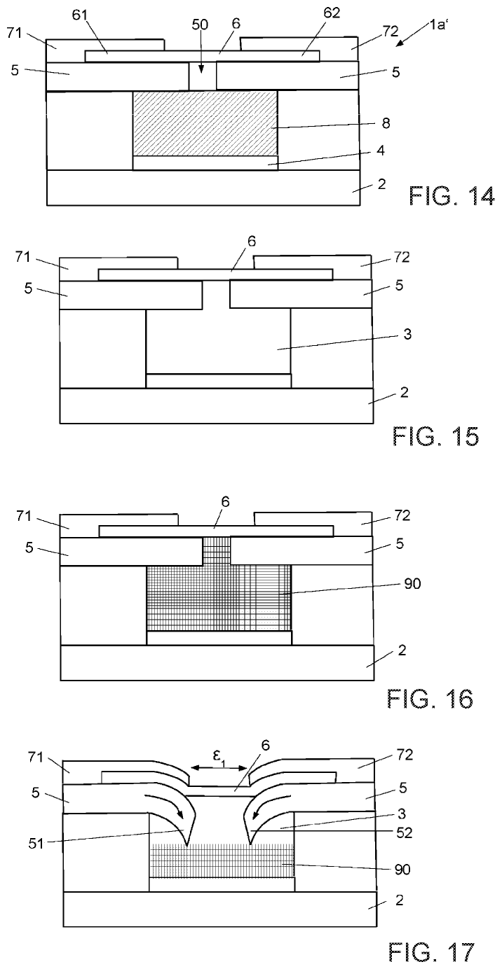

FIGS. 14 to 17 schematically show method steps of a further embodiment of the method according to the invention for producing a nanoelectronic component structure, in each case in a sectional side view through the structure formed in each case;

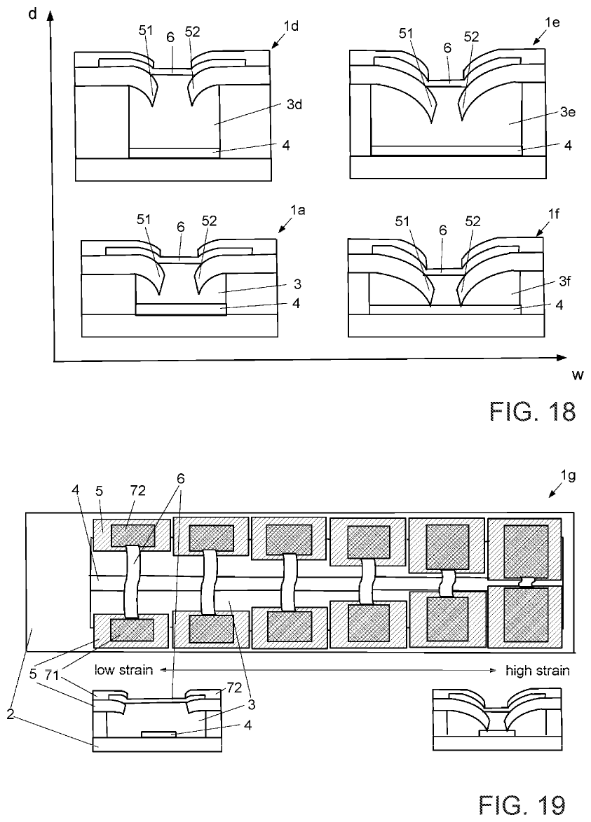

FIG. 18 schematically demonstrates the adjustability of the tension and of the electrostatic coupling to the corresponding control electrode on nanoelectronic component structures according to the invention;

FIG. 19 schematically shows a nanoelectronic component structure according to the invention in the form of a CNT-FET array with individual tensioning of the corresponding nanostructures;

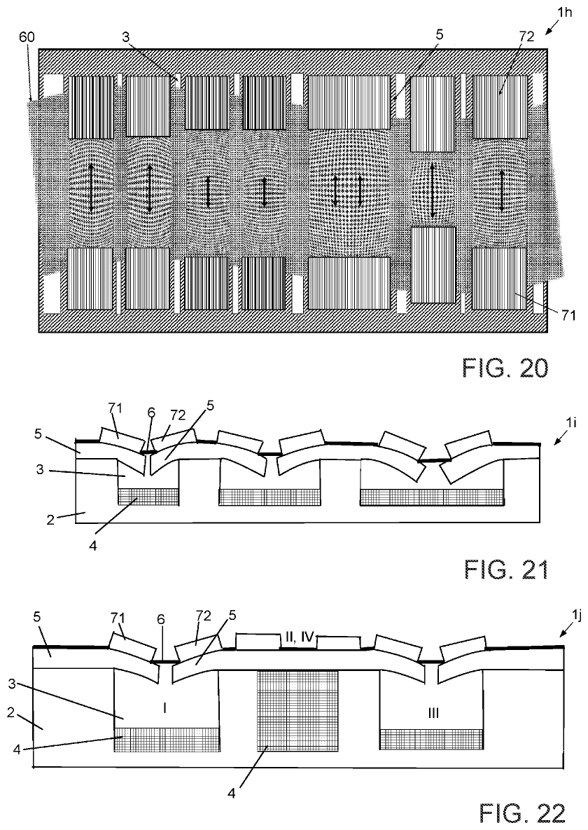

FIG. 20 schematically shows a further nanoelectronic component structure according to the invention having a heterogeneously distorted graphene layer;

FIG. 21 schematically shows yet another nanoelectronic component structure according to the invention in the form of an array having variable tension states within a nanomaterial domain, and

FIG. 22 schematically shows a nanoelectronic component structure according to the invention in the form of a sensor half bridge formed within a nanomaterial domain.

FIGS. 1 to 3 schematically show possible embodiments of nanoelectronic component structures 1a, 1b, 1c according to the invention, in each case in a sectional side view.

The nanoelectronic component structure 1a can be regarded as a type of “core cell” of a prestressed nanomaterial system that can be formed with the present invention, and is therefore well suited for demonstrating the invention. The nanoelectronic component structure 1a has a substrate 2, a cavity 3 formed therein, a control electrode 4 formed on a base 31 of the cavity 3, arms 5 that each partially overlap the cavity 3 and a nanostructure 6 resting on both free arm ends 51, 52 of the arms 5 and covered on both sides by a contact electrode 71, 72. Due to the fact that the two arms 5 hang into the cavity 3, the nanostructure 6 resting on the arm ends 51, 52 is tensioned, as shown schematically by the arrow ci.

The nanostructure 6 can consist of a 1D or 2D nanomaterial extending from a few hundred nanometers to several micrometers. The nanostructure 6 has targetedly set basic properties, such as chirality, diameter and/or MW/SW. As will be explained in more detail below, the tension in the nanostructure 6 was produced using conventional surface-technological process steps. In the embodiment shown, a tensile stress was introduced in a controlled manner into the nanostructure 6, along a spatial axis.

The nanoelectronic component structure 1b from FIG. 2 has a substrate 2 into which two different nanomaterial structures are introduced. A first of these nanomaterials structures has, similarly to the nanoelectronic component structure 1a, a cavity 3 formed in the substrate 2, a control electrode 4 formed on a base 31 of the cavity 3, arms 5 each partially overlapping the cavity 3 and a nanostructure 6 resting on both free arm ends 51, 52 of the arms 5 and covered on both sides by a contact electrode 71, 72. A second of the nanomaterial structures is formed without a cavity, i.e. on the substrate surface, and has a control electrode 4 over which one of the arms 5 runs and which is arranged opposite a further nanostructure 6b which is contacted on both sides by contact electrodes 71, 72.

In this arrangement, the tensioned nanostructure 6, and the untensioned nanostructure 6b serving as an internal reference for the nanostructure 6 are located on the same substrate 2.

The nanoelectronic component structure 1c from FIG. 3 has a substrate 2 into which two different nanomaterial structures are also introduced. Similarly to the nanoelectronic component structure 1a from FIG. 1, both of these nanomaterial structures have a cavity 3, 3a formed in the substrate 2, a control electrode 4, 4a formed on a base 31, 31a of the corresponding cavity 3, 3a, arms 5 that each partially overlap the corresponding cavity 3, 3a, and in each case a nanostructure 6, 6a which rests on the corresponding free arm ends 51, 52; 51a, 52a of the arms and is in each case covered by a contact electrode 71, 72 on both sides. However, the geometries of the cavities 3, 3a, and thus also the curvatures of the arm ends 51, 52; 51a, 52a into the corresponding cavity 3, 3a, and thus also the tensions ε₁, ε₂ of the two nanostructures 6, 6a are different.

As indicated schematically by the dashed lines in FIGS. 2 and 3, the corresponding nanostructures 6, 6b and 6, 6a, respectively, are each formed from the same nanomaterial. The nanoelectronic component structure 1c schematically shown in FIG. 3 thus makes it possible to locally control different tension states within domain boundaries of the 1D or 2D nanomaterials used in each case for the nanostructures 6, 6a.

FIGS. 4 to 12 schematically show method steps of an embodiment of the method according to the invention for producing the nanoelectronic component structure 1a from FIG. 1.

As can be seen in FIG. 4, a substrate 2 is first provided.

In the method step shown in FIG. 5, a control electrode 4 is produced on the substrate 2.

Then, as shown in FIG. 6, a spacer layer 2′ is deposited, which does not have to consist of the same material as the substrate 2 but is functionally associated with the substrate 2 in the present invention.

In the method step shown in FIG. 7, a cavity 3 is formed in the spacer layer 2′. The control electrode 4 is located on a base 31 of the cavity 3.

The cavity 3 is subsequently filled with a sacrificial material 8, as shown in FIG. 8. The sacrificial material 8 can be of organic or inorganic origin. The sacrificial material 8 is preferably selected depending on the choice of material and the degree of tension in the arms 5 produced in the subsequent method step, and on the compatibility with the entire production process.

Thereafter, as can be seen in FIG. 9, arms 5 are deposited on the spacer layer 2′ and the sacrificial material 8 on both sides of, and above, the cavity 3, a gap 50 resulting between arm ends 51, 52 of the arm 5, above the cavity 3. In other embodiments of the present invention, a single arm 5 can also be designed in a manner extending over the cavity 3 and, instead of the gap 50, a predetermined breaking point can be formed above the cavity 3 in this arm 5.

The arms 5 can either be produced by stacking at least two thin layers of different materials, or produced by a single thin layer having a process-induced tension within the layer during the layer deposition thereof. As a result, the intrinsic tension in the arm 5 produced in this way can be precisely set and initially fixed, since it adheres to the sacrificial material 8 lying underneath.

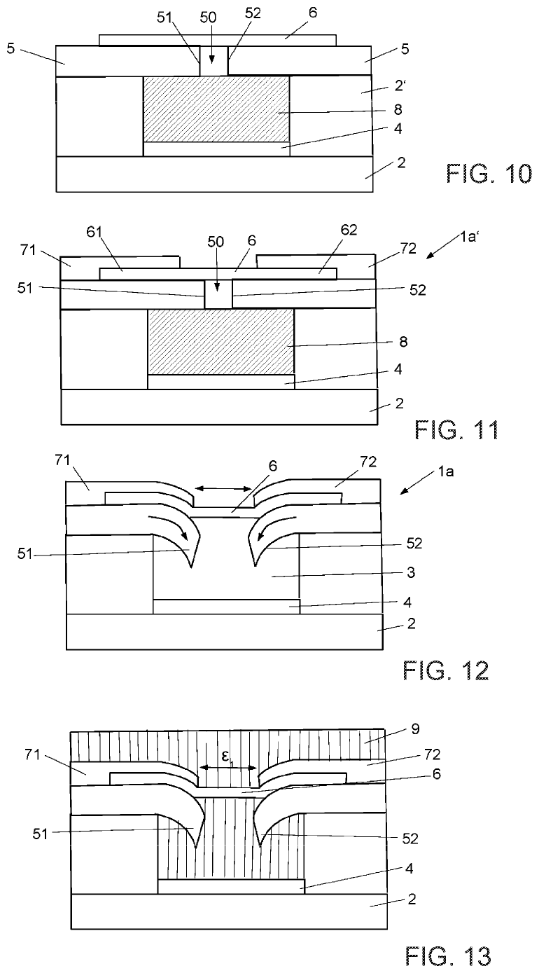

Subsequently, as can be seen in FIG. 10, a nanostructure 6 is applied to the arm 5 serving as a carrier. Various methods can be used for applying the corresponding nanostructure 6. For example, selected and functionalized nanomaterials, such as carbon nanotubes (CNTs), can be applied in dispersed form by means of self-arrangement, printing, dielectrophoresis or thermophoresis, etc. as the nanostructure 6.

Alternatively, transfer processes for applying the nanostructure 6 can be used, which offer extended control options with regard to the tension in the nanostructure 6. For this purpose, e.g. CVD (chemical vapor deposition) processes are used for the synthesis of, for example, CNT, graphene, MoS₂ or WS, or also ALD (atomic layer deposition) processes for MoS₂ on a source substrate. A polymer-based transfer method based on adhesion promoters and temporary transfer carriers, such as a film, transfers the nanostructure 6 to the substrate 2, which is for example pre-processed as above.

In a particularly advantageous embodiment of the present invention, the process of transferring the nanostructure 6 can be carried out on a controlled stretched transfer carrier. By means of this procedure, extensive basic tensioning of the nanostructures of the corresponding nanoelectronic component structure can be achieved, which leads to homogenization, alignment and smoothing of the respective nanostructures.

In a next method step, shown in FIG. 11, a contact electrode 71, 72 is deposited in each case on both nanostructure ends 61, 62 of the nanostructure 6. As a result, the intermediate product 1a′ according to the invention is produced, as shown schematically in FIG. 11.

Thereafter, as shown schematically in FIG. 12, the sacrificial material 8 is removed from the cavity 3. The removal of the sacrificial material 8 can be done by a suitable selectively subtractive method of a surface technology, such as by dissolving or etching out. The sacrificial material 8 can be removed chemically and/or thermally and/or by means of dissolving in water or another solvent and/or by ultrasound.

As shown schematically in FIG. 12, the removal of the sacrificial material 8 simultaneously causes a relaxation of the pre-tensioned arms 5 located thereabove. Depending on the selected materials and deposition characteristics, the arms 5 are bent into the plane or out of the plane.

In the embodiment shown, the nanostructure 6 positioned in a targeted manner on two opposite arms 5 and fixed at its nanostructure ends 61, 62 experiences a tensile force at the moment of relaxation of the arms 5, since the fixed points of the nanostructure 6 on the arm ends 51, 52 move away from one another. At the same time, the nanostructure 6 is released.

By the sacrificial material 8 being dissolved out, the gap 50 between the arm ends 51, 52 also changes. The nanostructure 6 spans over this gap 50 and forms, in the region between the fixed points, a free one-dimensional or two-dimensional structure of nanomaterial, tensioned in a manner specific to the location. As a result of the removal of the sacrificial material 8, the shown nanoelectronic component structure 1a is thus produced.

The magnitude of the tensile force generated, and thus the tension in the nanostructure 6, is defined by a targetedly produced geometric design of the arms 5. The overhang length, width and height of the arm ends 51, 52, which results after removal of the sacrificial material 8, the targetedly introduced intrinsic tension and the materials chosen for the arms 5 are the decisive parameters for producing a desired bending radius or a certain tension in the nanostructure 6. The bending radius and overhang height are the determining factors for establishing the maximum deflection of the arm ends 51, 52, and are used thereafter for more precise limitation and determination of the change in length of the nanostructure 6. Furthermore, the position where the nanostructure 6 is fixed on the corresponding arm 5 represents an important factor. The accuracy, resolution and reproducibility is limited here by the structuring method used. Typically, electron beam lithography is used, but does not exclude the use of alternative microstructuring and nanostructuring methods. In the embodiment shown, this aforementioned fixing process is realized by means of the contact electrodes 71, 72, which simultaneously serve to electrically contact the nanostructure 6.

The surface technology described above is not limited to a specific substrate 2, and can also be integrated into hetero system integration technology for system-on-chip or post-back end of line, for example.

The tension state of the arms 5 and/or of the nanostructure 6 can be set by additive coating methods established in microtechnology and nanotechnology. By applying structuring methods, such as optical lithography, this retrospective adaptation step is possible in a manner specific to the location, or globally, via the substrate 2.

In the embodiment shown, the nanostructure 6, which is in the stressed state, does not touch the base 31 of the cavity 3 and thus hangs freely.

In other embodiments of the present invention, the arms 5 used in each case can consist of at least two layers and be intrinsically tensioned in such a way that, upon exposure, this leads to bending in the direction of the substrate 2 with impact, and, in the case of a comparatively high tensile force in the arms 5, the change in length of the nanostructure 6 is determined by the depth d and width w of the cavity 3, which can also be seen in FIG. 18.

FIG. 13 schematically shows the nanoelectronic component structure 1a from FIG. 1 or 12, the cavity 3 and also the region above the tensioned nanostructure 6 being filled with a filler material 9. By means of the filler material 9, the arm ends 51, 52 are fixed in their curved position in the cavity 3, and the preload of the nanostructure 6 are “frozen”.

As can be seen from the nanoelectronic component structures 1a, 1b, 1c shown by way of example, it is possible, by means of the present invention, to generate free, locally individually tensioned 1D or 2D nanomaterial structures by combining layers or layer stacks having intrinsic layer tensions, sacrificial structures and 1D or 2D nanostructures 6, 6a, 6b arranged in a controlled manner.

FIGS. 14 to 17 schematically show method steps of a further embodiment of the method according to the invention for producing a nanoelectronic component structure, in each case in a sectional side view through the structure formed in each case.

FIG. 14 corresponds to the method state from FIG. 11. The further embodiment of the method according to the invention described below thus begins with an embodiment of the intermediate product 1a′ according to the invention. The method steps for producing the intermediate product 1a′ correspond to the method steps described above with regard to FIGS. 4 to 11.

In the method step shown in FIG. 15, the sacrificial material 8 is dissolved out or etched out of the cavity 3.

A filler material 90 is then introduced into the cavity 3 in the method step shown in FIG. 16, the arm ends 51, 52 of the arms 5 adhering to the filler material 90.

In the method step in FIG. 17, the structure from FIG. 6 is exposed to an increased temperature, at which the filler material 90 shrinks. Due to the shrinkage of the filler material 90 in the cavity 3, the arm ends 51, 52 bend into the cavity 3. The nanostructure 6 is thereby tensioned.

FIG. 18 schematically demonstrates the adjustability of the tension and the electrostatic coupling to the corresponding control electrode 4 on nanoelectronic component structures 1a, 1d, 1 e, lf according to the invention. In this case, the depth of the corresponding cavity increases in the arrow direction d, while the width of the corresponding cavity increases in the arrow direction w. That is to say that the cavity 3d is deeper than the cavity 3, the cavity 3e is deeper than the cavity 3f, the cavity 3e is wider than the cavity 3d and the cavity 3f is wider than the cavity 3. With regard to the further features of the nanoelectronic component structures 1a, 1d, 1e, 1f, reference is made to the above description of the nanoelectronic component structure 1a, which also applies to the nanoelectronic component structures 1d, 1 e, lf.

As can be seen from the drawings in FIG. 18, a wide cavity having a small depth d leads to increased bending of the corresponding arm ends 51, 52 into the corresponding cavity. In this case, as can be seen from the nanoelectronic component structure 1f, bending of the arm ends 51, 52 can be of such a size that they rest on the control electrode 4, which limits the degree of bending and thus tension of the nanostructure 6.

FIG. 19 schematically shows a nanoelectronic component structure 1g according to the invention, integrated into a single substrate 2 having a single cavity 3 and a single control electrode 4 formed on the base of the cavity 3, having a plurality of nanostructures 6 spanning the cavity 3. The nanoelectronic component structure 1g forms a CNT-FET array having individual tension in the corresponding nanostructures 6. The different degrees of tension in each of the nanostructures 6 is achieved here by the different geometries of the arms 5, the nanostructures 6 and the contact electrodes 71, 72. As shown schematically in FIG. 19 by the double-headed arrow, the tension in a region of low strain up to high strain of the corresponding nanostructure 6 can thus be set individually.

In other embodiments of the present invention, a similar array to that in FIG. 19 can also be formed with changing geometry of the cavity 3, such as gradually changing cavity depth and/or width.

Furthermore, it is possible to provide a plurality of control electrodes 4 on the cavity base or over the corresponding passivation. The corresponding control electrode(s) 4 serve(s) for electrostatic control of the corresponding nanostructure(s) 6 and/or for adjusting at least one working point.

FIG. 20 schematically shows a further nanoelectronic component structure 1h according to the invention, having a heterogeneously distorted graphene layer 60. The graphene layer 60 has a continuous lattice structure.

FIG. 21 schematically shows yet another nanoelectronic component structure 1i according to the invention in the form of an array having variable tension states in an identical nanomaterial within a nanomaterial domain. In the embodiment shown, the corresponding nanostructures spanning the cavities 3 are designed as differently tensioned segments strung together along a spatial axis of the same 1D or 2D nanomaterial structure, having targetedly set basic properties, such as chirality, diameter and/or MW/SW. The geometries of each of the cavities 3 located under the nanostructures are different. The individual segments can be individually modulated in their properties, for example with regard to their band gap or oscillation frequency, by the degree of expansion which is freely adjustable for each segment. A one-dimensional sequence of different basic elements of the nanoelectronic component structure 1i, which is independent of the material variance, is thus created, which component belongs, viewed as a closed unit, to a new class of multi-functional nanoelectronic component structures, based on 1D or 2D nanomaterial systems, which can be configured in a segment-specific manner.

Due to the different tensions in the nanostructures 6, these have a targeted modification of the band structure, for example the band gap. This can be designed such that a modification of the electronic interaction between adsorbants or chemisorbers and the nanomaterial of the nanostructures 6 is associated therewith.

The nanoelectronic component structure 1i can therefore be used, for example, as a biosensor which, due to the specifics of the different tension states on a substance to be detected, can identify this by means of deep-learning approaches. The nanoelectronic component structure 1i can also be used for the specific detection of chemical or gaseous substances.

In this case, the corresponding miniaturized biological and/or chemical sensor and/or gas sensor, designed on the basis of the present invention, can have sensitivities in the atomic mass range and function in a mass-spectral manner.

As a measurement signal of the nanoelectronic component structure 1i, the resonant frequency of the spanned and tensioned nanostructures 6 can be read out capacitively between the corresponding nanostructure 6 and the control electrode 4. The resonant frequency can be controlled by modifying the mechanical tension introduced, and therefore the selectivity with regard to interaction with a certain substance can be achieved.

The measuring mechanism can, for example, be based on a change in mass of at least one respectively oscillating nanostructure 6 of the nanoelectronic component structure 1i, which results from atoms or molecules of a substance accumulating on the nanostructure 6.

Furthermore, certain species can be selectively chemisorbed by the differently tensioned nanostructures 6.

In certain embodiments of the present invention, small mass bodies can be provided in or on the at least one nanostructure 6, before or after it is tensioned. As a result, broadband inertial sensors having vibration detection above 100 kHz and 3D accelerations can be produced.

FIG. 22 schematically shows a nanoelectronic component structure 1j according to the invention in the form of a sensor half bridge formed within a nanomaterial domain of an identical nanomaterial. The sensor half bridge has variable diagonal elements I and III and adjustable compensation elements II and IV, for example due to environmental influences to be detected, such as mechanical and/or optical and/or chemical environmental influences. The half-bridge circuit is monolithically manufactured in the same material, i.e. within one domain, and thus represents a highly sensitive, drift-free measuring circuit. The diagonal elements I and III functioning as sensor elements can, due to the technology according to the invention that is used, have a piezo-resistance having a high Gauge factor (e.g. of 400) for their tensioning, while the two compensation elements II and IV remain untensioned due to layout-determined omission of the tensioning structure.

The half bridge shown can find space in highly miniaturized form, for example on a surface of <10 μm², including the half-bridge wiring.

Both extremely small compressions, and also expansions, can be detected in a piezoresistive manner using nanoelectronic component structures of this type. In addition, on this basis, 1D or 2D nanomaterial-based piezoresistive sensors, of an atom-layer thickness, can be realized in full bridge configuration.

1-29. (canceled)

30. An intermediate product for producing a nanoelectronic component structure, the intermediate product comprising:
a substrate having at least one cavity formed therein;
at least one nanostructure which at least partially spans said at least one cavity;
a sacrificial material at least partially filling said at least one cavity, said sacrificial material being selectively etchable or dissolvable relative to a material of said substrate;
a contact electrode; and
at least one arm on at least one side of said at least one cavity which partially overlaps said at least one cavity and has a gap being formed above said at least one cavity or said least one arm spanning said at least one cavity and has a predetermined breaking point which is formed above said at least one cavity, said at least one nanostructure being disposed on said at least one arm, in each case spanning said gap or said predetermined breaking point, and in each case being covered by said contact electrode on both sides of said gap or said predetermined breaking point.

31. The intermediate product according to claim 30, wherein said at least one arm is one of a plurality of arms and at least one of said arms is under mechanical tensile stress.

32. The intermediate product according to claim 30, wherein said at least one nanostructure contains graphene and/or at least one carbon nanotube.

33. The intermediate product according to claim 30, further comprising at least one control electrode disposed or formed in said at least one cavity.

34. A nanoelectronic component structure, comprising:
a substrate having at least one cavity formed therein;
at least one nanostructure at least partially spanning said at least one cavity;
contact electrodes; and
at least one arm partially overlapping said at least one cavity, at least on one side of said at least one cavity, and is curved or shrunk at its arm end projecting over or into said at least one cavity, a gap being formed above said at least one cavity and said at least one nanostructure being disposed on said at least one arm, in each case spanning said gap, and being fixed between said at least one arm and said contact electrodes each formed on either side of said gap.

35. The nanoelectronic component structure according to claim 34, wherein said at least one nanostructure is mechanically tensioned between said contact electrodes.

36. The nanoelectronic component structure according to claim 34, wherein a side of said at least one nanostructure facing away from said substrate is more strongly tensioned than a side of said at least one nanostructure facing said substrate.

37. The nanoelectronic component structure according to claim 34, further comprising at least one control electrode disposed in said at least one cavity.

38. The nanoelectronic component structure according to claim 34, wherein:
said at least one nanostructure is one of a plurality of nanostructures; and
said substrate has a plurality of cavities formed therein and are each spanned by at least one of said nanostructures, at least two of said cavities having different widths and/or depths and/or lengths and/or at least two of said nanostructures having different widths and/or lengths and/or at least two of said nanostructures being aligned and/or mechanically tensioned in different spatial directions.

39. The nanoelectronic component structure according to claim 34, wherein said at least one nanostructure contains graphene and/or at least one carbon nanotube.

40. The nanoelectronic component structure according to claim 34, further comprising a shrunk filler material disposed in said at least one cavity, on said shrunk filler material, said arm end of said at least one arm rests or into which said arm end of said at least one arm is incorporated.

41. The nanoelectronic component structure according to claim 34, further comprising a filler material, wherein arm ends projecting into said at least one cavity are fixed by said filler material introduced into said at least one cavity.

42. The nanoelectronic component structure according to claim 41, wherein said at least one nanostructure is covered with said filler material.

43. The nanoelectronic component structure according to claim 34, wherein said at least one nanostructure is one of a plurality of nanostructures; and
further comprising at least one mass body disposed on each of said nanostructures.

44. A bridge circuit, comprising:
bridge elements each having or based on the least one nanoelectronic component structure according to claim 34.

45. The bridge circuit according to claim 44, where said at least one nanoelectronic component structure has a contiguous nanostructure lattice on which said bridge elements are disposed.

46. A method for producing a nanoelectronic component structure, which comprises the steps of:
making at least one cavity in a substrate and the at least one cavity is bridged by at least one nanostructure;
filling at least partially the at least one cavity with a sacrificial material;
forming on the at least one cavity at least partially filled with the sacrificial material either at least one arm which partially overlaps the at least one cavity, at least on one side of the at least one cavity, and has a gap formed above the at least one cavity, or at least one arm which spans the at least one cavity and has a predetermined breaking point above the at least one cavity;
forming the least one nanostructure disposed on the at least one arm so as to span the gap or the predetermined breaking point;
forming in each case a contact electrode on nanostructure ends of the at least one nanostructure formed on both sides of the at least one cavity; and
subsequently at least partially etching out or dissolving out the sacrificial material out of the at least one cavity, and, if present, the predetermined breaking point is broken through.

47. The method according to claim 46, which further comprises forming the at least one arm from at least two layers of materials, using process parameters and having layer thicknesses of such a type that it is under mechanical tensile stress directly after layer deposition steps.

48. The method according to claim 46, which further comprises shrinking at least one arm end of the at least one arm by means of tempering.

49. The method according to claim 46, which further comprises disposing or forming at least one control electrode in the at least one cavity before the at least one cavity is at least partially filled with the sacrificial material.

50. The method according to claim 46, which further comprises:
forming a plurality of nanostructures; and
forming a plurality of cavities in the substrate, wherein at least two of the cavities are each configured having different widths and/or depths and/or lengths and/or at least two of the nanostructures are configured to be aligned in different spatial directions in each case and/or to be mechanically tensioned in different spatial directions in each case.

51. The method according to claim 46, wherein the at least one nanostructure is formed from graphene and/or at least one carbon nanotube.

52. The method according to claim 46, wherein after at least partially etching or dissolving the sacrificial material out of the at least one cavity, introducing at least one filler material into the at least one cavity and the filler material is subsequently shrunk by tempering and/or curing.

53. The method according to claim 46, which further comprises fixing at least one arm end projecting into the at least one cavity by introducing a filler material into the at least one cavity.

54. The method according to claim 52, which further comprises applying the at least one filler material to the at least one nanostructure.

55. The method according to claim 52, wherein the at least one filler material has at least one silsesquioxane and/or at least one crosslinking polymer.

56. The method according to claim 50, which further comprising forming at least one mass body on each of the at least one nanostructures.

57. The method according to claim 56, wherein the at least one mass body is formed from the at least one arm when the sacrificial material is at least partially etched or dissolved out of the at least one cavity.

58. The method according to claim 46, which further comprises applying the at least one nanostructure to the at least one arm by means of a stretched transfer carrier.
